(19) United States
(12) Patent Application Publication
(10) Pub. No.: US 2025/0231215 A1
(43) Pub. Date: Jul. 17, 2025

(54) Inertial Sensor, Electronic Component, And Method Of Manufacturing Inertial Sensor

(71) Applicant: SEIKO EPSON CORPORATION, Tokyo (JP)

(72) Inventors: Teruo TAKIZAWA, Matsumoto (JP); Tomonaga KOBAYASHI, Chino (JP)

(21) Appl. No.: 19/021,880

(22) Filed: Jan. 15, 2025

(30) Foreign Application Priority Data
Jan. 16, 2024 (JP) 2024-004389

(51) Int. Cl. G01P 15/125; G01P 1/02; G01P 15/18

(52) U.S. Cl. CPC G01P 15/125; G01P 1/02; G01P 15/18

(57) ABSTRACT

An inertial sensor or an electronic component includes a base body, a lid body, a functional element disposed between the base body and the lid body, and a metal eutectic layer configured to bond the base body and the lid body to each other on a periphery of the functional element, wherein in the metal eutectic layer, a plurality of first regions having a first metal as a main component and having a face-centered cubic lattice structure, and a second region having a second metal as a main component and having a diamond structure are present, and adjacent to each other.

The present application is based on, and claims priority from JP Application Serial Number 2024-004389, filed Jan. 16, 2024, the disclosure of which is hereby incorporated by reference herein in its entirety.

### BACKGROUND

### 1. Technical Field

The present disclosure relates to an inertial sensor, an electronic component, and a method of manufacturing an inertial sensor.

### 2. Related Art

In the past, there has been known a sensor device including a base body having a cavity, a sensor element suspended in the cavity, and a lid body sealing the cavity. The base body and the lid body were bonded via a bonding material. The bonding material was required to have a high bonding strength and a high long-term reliability of sealing.

For example, US 2010/0059835 discloses use of an AlGe eutectic as the bonding material. According to this document, the concentration of Ge in the AlGe eutectic is uniform or a function of a distance from the lid body or the base body. In particular, it is disclosed that when a heat treatment is performed for a long time, the concentration of Ge becomes uniform.

US 2010/0059835 is an example of the related art.

However, in the technology disclosed in US 2010/0059835, there is a concern that the bonding strength with the bonding material may decrease. In addition, there is a concern that the long-term reliability of sealing may be reduced. Particularly, when the concentration of Ge decreases in accordance with the distance from the lid body, the AlGe eutectic layer cannot be realized at the base body side, and only the Al layer is formed, which may cause a deterioration of the bonding strength. Further, the prolonged heat treatment is preferable for the formation of a bonding layer having a uniform Ge concentration, but generates a hillock or the like in other metal interconnections such as an Al interconnection for extracting, for example, a detection signal to deteriorate the long-term reliability.

That is, an inertial sensor, an electronic component, and a method of manufacturing an inertial sensor, which have high bonding strength between the base body and the lid body, and are excellent in long-term reliability, have been demanded.

### SUMMARY

An inertial sensor according to an aspect of the present application is an inertial sensor of a capacitance change type including a base body, a lid body, a functional element disposed between the base body and the lid body, and a metal eutectic layer configured to bond the base body and the lid body to each other on a periphery of the functional element, wherein in the metal eutectic layer, a plurality of first regions having a first metal as a main component and having a face-centered cubic lattice structure, and a second region having a second metal as a main component and having a diamond structure are present, and adjacent to each other.

An electronic component according to an aspect of the present application includes a base body, a lid body, a functional element disposed between the base body and the lid body, and a metal eutectic layer configured to bond the base body and the lid body to each other on a periphery of the functional element, wherein in the metal eutectic layer, a plurality of first regions having a first metal as a main component and having a face-centered cubic lattice structure, and a second region having a second metal as a main component and having a diamond structure are present, and adjacent to each other.

A method of manufacturing an inertial sensor according to an aspect of the present application is a method of bonding a base body provided with a functional element and a lid body configured to cover the functional element to each other in a bonding region surrounding the functional element, the method including forming a first bonding part mainly made of a first metal in the bonding region in the base body, forming a second bonding part mainly made of a second metal in the bonding region in the lid body, aligning the first bonding part and the second bonding part to overlap each other and then stacking the base body and the lid body on one another to form a stacked body, a heating step of heating the stacked body, and a weighting step of applying a weight to the stacked body.

### BRIEF DESCRIPTION OF THE DRAWINGS

FIG. 1 is a plan view of an inertial sensor according to Embodiment 1.

FIG. 2 is a cross-sectional view of the inertial sensor along the line b-b in FIG. 1.

FIG. 3 is an enlarged view of a part c in FIG. 2.

FIG. 4 is a cross-sectional view of an essential part of a base body and a lid body to be bonded to each other.

FIG. 5 is a table showing a relationship of surface energy per unit area.

FIG. 6 is a flowchart representing a flow of a bonding method.

FIG. 7 is a side view illustrating a schematic configuration of a bonding apparatus.

FIG. 8 is a graph showing an example of a temperature profile in a heating step.

FIG. 9 is a perspective view of an essential part showing an electrical interconnection structure of a metal eutectic layer.

FIG. 10 is a cross-sectional view of an essential part of a base body and a lid body to be bonded to each other related to Embodiment 2.

FIG. 11 is a cross-sectional view of an essential part of a base body and a lid body to be bonded to each other related to Embodiment 3.

FIG. 12 is an enlarged view of a periphery of the metal eutectic layer after bonding.

FIG. 13 is a plan view of an inertial sensor according to Embodiment 4.

FIG. 14 is an exploded perspective view of an inertial measurement device.

FIG. 15 is a perspective view of a board.

### DESCRIPTION OF EMBODIMENTS

### Embodiment 1

### Configuration of Inertial Sensor

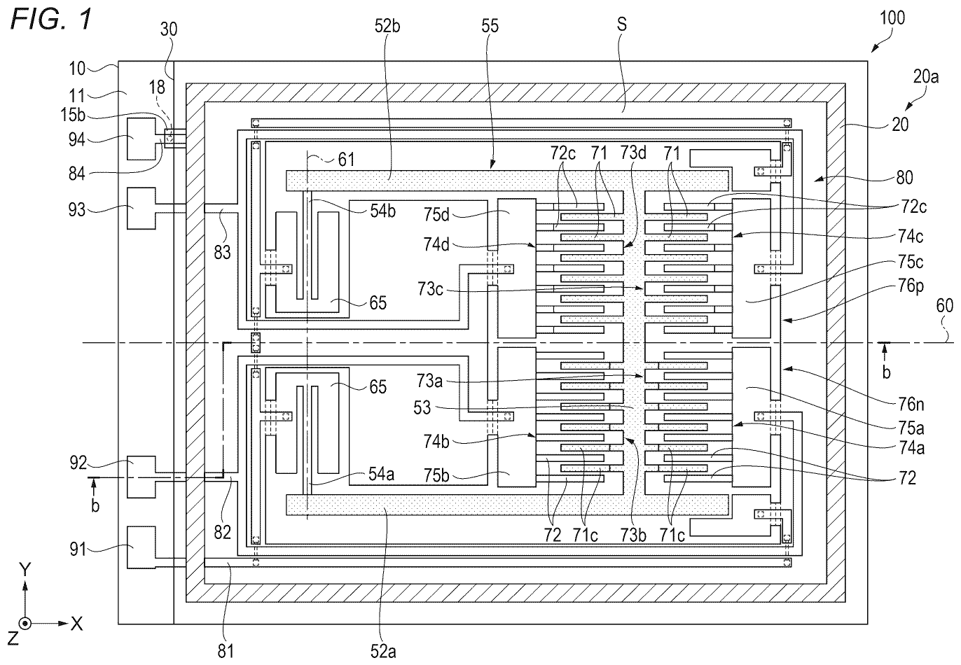

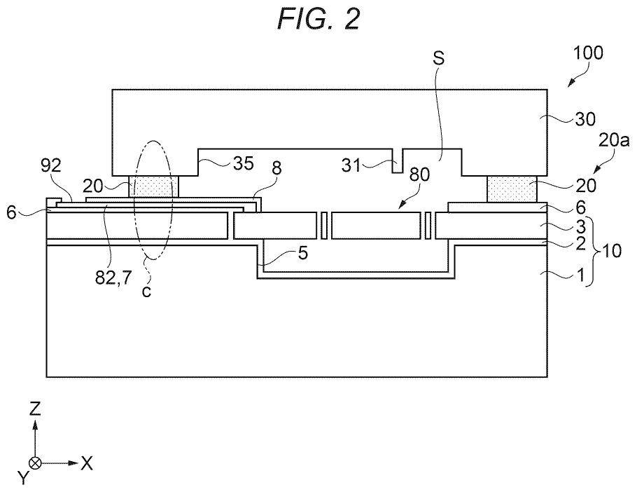

FIG. 1 is a plan view of an inertial sensor according to Embodiment 1. FIG. 2 is a cross-sectional view of the inertial sensor along the line b-b in FIG. 1.

A configuration of an inertial sensor 100 according to the present embodiment will be described with reference to FIG. 1 and FIG. 2.

The inertial sensor 100 is, for example, an acceleration sensor that detects acceleration in a vertical direction. Note that an X axis, a Y axis, and a Z axis which are three axes perpendicular to each other are shown in the drawings. In the present embodiment, a Z-axis direction is defined as the vertical direction, but this is not a limitation. A direction along the X axis is referred to as an “X direction”, a direction along the Y axis is referred to as a “Y direction”, and a direction along the Z axis is referred to as a “Z direction”. Further, a tip side of an arrow in each axis direction is also referred to as “positive side”, and a base side of the arrow is also referred to as “negative side”. For example, the Y direction refers to both a direction toward the positive side in the Y direction and a direction toward the negative side in the Y direction. Further, the positive side in the Z direction is also referred to as “upper side”, and the negative side in the Z direction is also referred to as “lower side”. Further, in each of the drawings described below, in order to make the description easy to understand, dimensions and scales different from actual ones may be used in some cases.

The inertial sensor 100 is a uniaxial acceleration sensor formed of a MEMS (Micro Electro Mechanical Systems) device. Note that the inertial sensor 100 is not limited to the acceleration sensor, but is sufficiently an inertial sensor of a variable capacitance type, and may be, for example, an angular velocity sensor.

As shown in FIG. 2, the inertial sensor 100 includes a base body 10, a sensor element 80 disposed above the base body 10, an interconnection layer 7 drawn from the sensor element 80, a lid body 30 that covers the sensor element 80, and so on.

The base body 10 is an SOI (Silicon On Insulator) substrate, and is configured by stacking a substrate 1, an insulating layer 2, a semiconductor layer 3, and an interconnection layer 7 in this order along the Z direction. The substrate 1 is a single-crystal silicon substrate, and the insulating layer 2 is disposed on an upper surface of the substrate 1. The insulating layer 2 is an embedded insulating layer made of SiO₂.

The substrate 1 is provided with a recessed part 5 which is dug from a peripheral edge portion thereof. The recessed part 5 is a cavity, and is a region forming a housing space S for housing the sensor element 80. Due to the recessed part 5, there is provided a configuration in which a movable body 55 (FIG. 1) of the sensor element 80 is swingable. Note that the insulating layer 2 is disposed on a bottom surface of the recessed part 5 in FIG. 2, but can be eliminated.

The semiconductor layer 3 is a conductive silicon substrate doped with impurities such as phosphorus (P), boron (B), or arsenic (As). In a preferred example, the semiconductor layer 3 and the insulating layer 2 are bonded with Si—SiO₂ fusion bond.

The sensor element 80 is a functional element and is formed by etching and patterning the semiconductor layer 3. In a preferred example, a deep etching technique using a Bosch process is used. The sensor element 80 is fixed to the substrate 1 with fixing parts 65 (FIG. 1).

As a preferred example, a silicon substrate is used as the lid body 30. The lid body 30 is provided with a recessed part 35 which is dug from a peripheral edge portion thereof. The recessed part 35 is a region forming the housing space S for housing the sensor element 80. The recessed part 35 is provided with a stopper part 31 that is a protrusion for restricting an excessive oscillation of the movable body 55 of the sensor element 80.

The base body 10 and the lid body 30 are bonded to each other in a circumferential edge portion thereof with a metal eutectic layer 20. In a preferred example, the housing space S is filled with an inert gas such as nitrogen, helium, or argon, and hermetically sealed. Note that approximately atmospheric pressure or a vacuum state is preferably set in a usage temperature environment of about −40° C. to 120° C. For example, when the sensor element 80 is an acceleration sensor, the housing space S preferably has pressure close to the atmospheric pressure, and when the sensor element 80 is an angular velocity sensor, the housing space S preferably has vacuum pressure.

### Configuration of Sensor Element

As shown in FIG. 1, the sensor element 80 as a functional element is an acceleration sensor that detects the acceleration in the Z direction, and adopts a so-called unilateral seesaw structure in which the movable body 55 swings centering on an oscillation axis 61.

The sensor element 80 includes the fixing parts 65, the movable body 55 which is swingable about the oscillation axis 61 passing through the center of the fixing part 65 and parallel to the Y axis, a first torsion spring 54a and a second torsion spring 54b which couple the fixing parts 65 and the movable body 55, and so on. The fixing parts 65 are fixed to a pedestal portion (not shown) protruding from the substrate 1 (FIG. 2). The periphery of the pedestal portion forms the recessed part 5 (FIG. 2) to form the configuration in which the movable body 55 is swingable. Note that in FIG. 1, a line segment which is perpendicular to the oscillation axis 61 and passes through the center of the sensor element 80 along the X axis is defined as a center line 60.

The movable body 55 includes a first bar 52a extending from the first torsion spring 54a toward the positive X direction, a second bar 52b extending from the second torsion spring 54b toward the positive X direction, and a third bar 53 coupling the first bar 52a and the second bar 52b to each other.

The third bar 53 is provided with four movable electrode groups 73a to 73d each having a comb-like shape.

The movable electrode group 73a is formed of six movable electrodes 71c extending toward the positive X direction from the third bar 53 at the negative Y side of the center line 60.

The movable electrode group 73b is formed of six movable electrodes 71c extending toward the negative X direction from the third bar 53 at the negative Y side of the center line 60. Note that the number of movable electrodes 71c is not limited to six, and is sufficiently two or more.

The movable electrode groups 73c and 73d are disposed at the positive Y side at positions line symmetrical about the center line 60 as an axis of symmetry with respect to the movable electrode groups 73a and 73b, respectively.

Further, at the substrate 1 (FIG. 2) side, fixed electrode groups 74a to 74d respectively opposed to the movable electrode groups 73a to 73d are provided.

The fixed electrode group 74a includes a support part 75a fixed to the substrate 1 and seven fixed electrodes 72 extending toward the negative X direction from the support part 75a.

The fixed electrode group 74b includes a support part 75b fixed to the substrate 1 and seven fixed electrodes 72 extending toward the positive X direction from the support part 75b. Note that the number of fixed electrodes is not limited to seven, and is sufficiently a number corresponding to the number of movable electrodes 71c.

The fixed electrode groups 74c and 74d are disposed at the positive Y side at positions line symmetrical about the center line 60 as an axis of symmetry with respect to the fixed electrode groups 74a and 74b, respectively.

A detector configured with the fixed electrode group 74a and the movable electrode group 73a and a detector configured with the fixed electrode group 74b and the movable electrode group 73b are collectively referred to as an N-type detector 76n.

In the N-type detector 76n, a parallel plate type capacitance is formed by the fixed electrode 72 and the movable electrode 71c disposed to be opposed to each other. The capacitance changes in accordance with a change in an overlapping area between the fixed electrode 72 and the movable electrode 71c due to a displacement of the movable electrode 71c by the acceleration.

Similarly, a detector configured with the fixed electrode group 74c and the movable electrode group 73c and a detector configured with the fixed electrode group 74d and the movable electrode group 73d are collectively referred to as a P-type detector 76p. In the P-type detector 76p, a parallel plate type capacitance is formed by the fixed electrode 72c and the movable electrode 71 disposed to be opposed to each other. The capacitance changes in accordance with a change in an overlapping area between the fixed electrode 72c and the movable electrode 71 due to a displacement of the movable electrode 71 by the acceleration.

The movable electrodes 71c of the N-type detector 76n are thinner in thickness in the Z direction than the movable electrodes 71 of the P-type detector 76p. Particularly, the movable electrodes 71c are each thinned by being cut in a stepwise manner in the middle in the extending direction from the same thickness as that of the third bar 53 at the base. Accordingly, the thicknesses of all the twelve movable electrodes 71c at the positive Z side are thinned in portions opposed to the fixed electrodes 72.

The fixed electrodes 72c of the P-type detector 76p are thinner in thickness in the Z direction than the fixed electrodes 72 of the N-type detector 76n. Particularly, the fixed electrodes 72c are each thinned by being cut in a stepwise manner in the middle in the extending direction from the thickness in the base at the support parts 75c, 75d side. Accordingly, the thicknesses of all the fourteen fixed electrodes 72c at the positive Z side are thinned in portions opposed to the movable electrodes 71.

Due to such a configuration, when the acceleration is generated in the positive Z direction, the overlapping area decreases in the N-type detector 76n, and the overlapping area is maintained in the P-type detector 76p. Further, when the acceleration in the negative Z direction is generated, the overlapping area is maintained in the N-type detector 76n, and the overlapping area decreases in the P-type detector 76p.

Based on such a correlation, in the sensor element 80, it is possible to detect the acceleration in the positive Z direction and the acceleration in the negative Z direction by performing the differential detection of a change in the overlapping area in the N-type detector 76n and the P-type detector 76p as a change in electrostatic capacitance.

### Planar Shape of Bonding Region

As shown in FIG. 1, the base body 10 has a substantially rectangular shape, and the short side at the negative side in the X direction forms a protruding portion 11 protruding from a short side of the lid body 30. Terminals 91 to 94 for external coupling are provided to the protruding portion 11.

The terminal 91 is a movable electrode terminal and is electrically coupled to all the movable electrodes 71, 71c with an interconnection 81.

The terminal 92 is an N-type fixed electrode terminal, and is electrically coupled to all the fixed electrodes 72 of N-type detector 76n with an interconnection 82.

The terminal 93 is a P-type fixed electrode terminal, and is electrically coupled to all the fixed electrodes 72c of the P-type detector 76p with an interconnection 83.

The terminal 94 is a GND terminal and is electrically coupled to the metal eutectic layer 20 with an interconnection 84. Note that the coupling configuration between the terminal 94 and the metal eutectic layer 20 will be described later in detail.

The base body 10 and the lid body 30 are bonded in a bonding region 20a having a quadrangular annular shape surrounding the sensor element 80. The bonding region 20a is a quadrangular annular area slightly smaller than the outer circumferential edge of the lid body 30. The metal eutectic layer 20 is formed in the bonding region 20a. Further, the metal eutectic layer 20 is formed to cross the interconnections 81 to 83 in a plan view.

In other words, the inertial sensor 100 of the capacitance change type includes the base body 10, the lid body 30, the sensor element 80 as a functional element disposed between the base body 10 and the lid body 30, the interconnection layer 7 stacked on the sensor element 80, and the metal eutectic layer 20 for bonding the base body 10 and the lid body 30 to each other on the periphery of the sensor element 80.

### Details of Metal Eutectic Layer

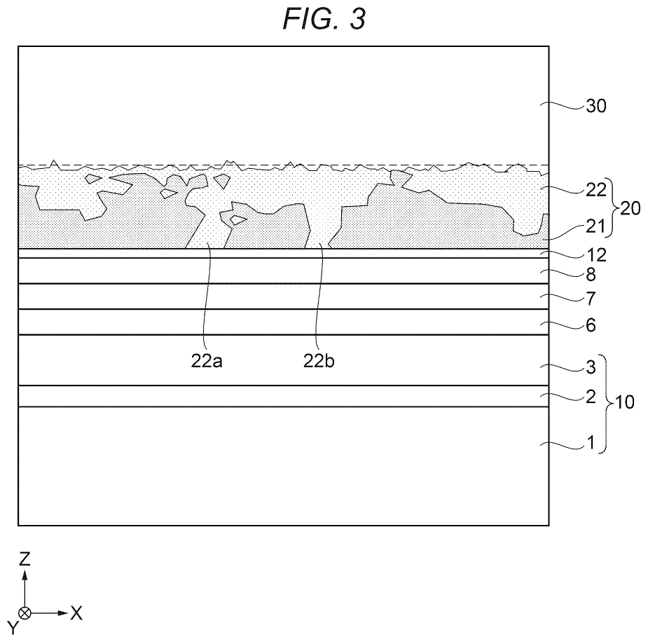

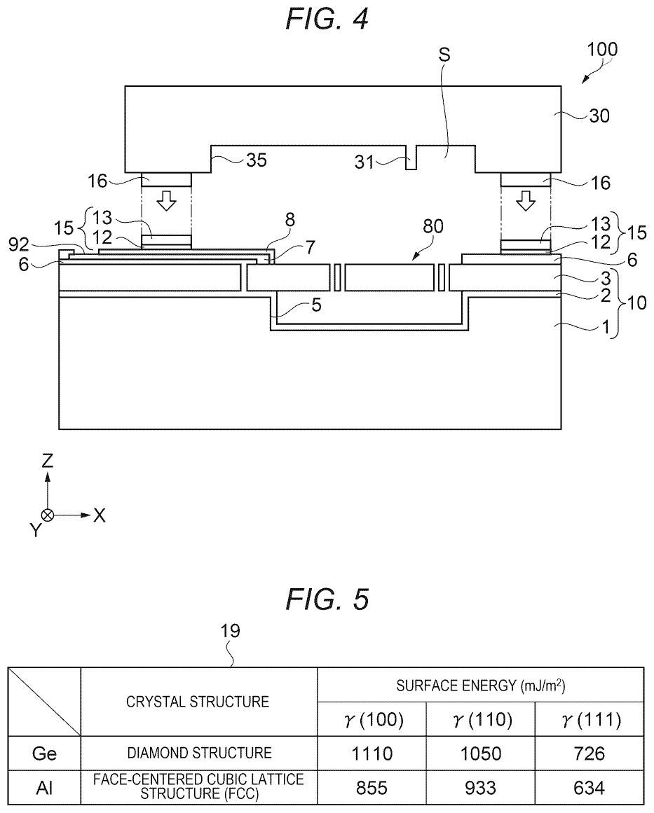

FIG. 3 is an enlarged view of a part c in FIG. 2. FIG. 4 is a cross-sectional view of an essential part of the base body and the lid body to be bonded to each other, and corresponds to FIG. 2.

FIG. 3 shows a cross-sectional surface of a portion where the bonding region 20a overlaps the interconnection 82 leading to the terminal 92. On the base body 10, an insulating layer 6, the interconnection layer 7 including the interconnection 82, an insulating layer 8, a barrier layer 12, the metal eutectic layer 20, and the lid body 30 are stacked in this order.

The insulating layer 6 is an interlayer insulating layer, and an SiO₂ layer in a preferred example. Note that the insulating layer 6 may be an SiN layer. The same applies to the insulating layer 8.

The interconnection layer 7 is formed of a plurality of layers, and has, for example, a four-layer structure in which Ti, TiN, AlCu, and TiN are stacked in this order from the bottom.

Here, the barrier layer 12 means a two-layer structure of Ti and TiN, and is a residual of a foundation layer of a first bonding part 15 (FIG. 4) at the base body 10 side before the formation of the metal eutectic layer 20. The Ti layer plays a role in an increase in the adhesiveness to the insulating layer 8, and the TiN layer plays a role in prevention of dispersion of Al from AlCu. When the barrier layer 12 is good in adhesiveness to the insulating layer 8, the Ti layer can be omitted from the barrier layer 12.

As shown in FIG. 4, before the formation of the metal eutectic layer 20, the base body 10 is provided with the first bonding part 15, and the lid body 30 is provided with a second bonding part 16. The first bonding part 15 has a two-layer structure of the barrier layer 12 and a first metal layer 13. The barrier layer 12 has a two-layer structure of Ti and TiN, and the first metal layer 13 is an AlCu layer. The second bonding part 16 is a Ge layer as a second metal. However, Cu in the AlCu layer is mixed for the purpose of preventing electromigration, and the content rate thereof is low as described later. Accordingly, a main component of the first metal layer 13 is Al. Meanwhile, the second bonding part 16 is a Ge layer as the second metal. The second bonding part 16 is also referred to as a second metal layer 16. In other words, the main component of the first metal is Al, and a main component of the second metal is Ge.

The metal eutectic layer 20 is an eutectic layer obtained by eutectizing the first bonding part 15 and the second bonding part 16 with a bonding method described later to be bonded to each other. In general, the term “eutectic substance” means an alloy formed by solidifying a mixture in a liquid phase state of two or more kinds of metals.

An image of the metal eutectic layer 20 shown in FIG. 3 is obtained by faithfully tracing a microscope photograph of the eutectic layer.

As a result of elemental analysis, as shown in FIG. 3, the metal eutectic layer 20 is formed in a state where a first region 21 having the first metal of Al as a main component and a second region 22 having the second metal of Ge as a main component are adjacent to each other. The content rate of the first metal in the first region 21 is higher than the content rate of the first metal in the second region 22. The content rate of the second metal in the second region 22 is higher than the content rate of the second metal in the first region 21.

The second region 22 extends widely along the lid body 30, but a part of the second region 22 reaches a boundary with the base body 10. For example, in FIG. 3, extending portions 22a, 22b reach the base body 10. The boundary between the first region 21 and the second region 22 is indented and very complicated. Further, a portion where the second region 22 extends is larger in the second region 22 than in the first region 21.

The distribution of Ge in the metal eutectic layer 20 is not uniform but is relatively high in the second region 22, and is homogenous in that region without a concentration gradient. However, even in the first region 21, Ge is uniformly present although small in amount. The first region 21 and the second region 22 are in contact with each other without a gap wherein the contact area is larger than the plane area of the bonding region 20a. That is, the first region 21 and the second region 22 are randomly fitted, and the bonding strength thereof is made extremely high. In other words, the contact area between the first region 21 and the second region 22 is larger than the area of the bonding region 20a in which the base body 10 and the lid body 30 are bonded to each other with the metal eutectic layer 20.

FIG. 5 is a table showing a relationship of surface energy per unit area. Note that the sources of Table 19 in FIG. 5 are Yokota et al., Journal of the Japan Society of Precision Engineering Volume 31 Issue 10 (1965) pp. 828-835, and H. W. Sheng et al., Phys. Rev. B 83, 134118 (2011).

In general, it is known that Ge has a diamond structure and Al has a face-centered cubic lattice structure, and when Ge is large in quantity as the main component of the eutectic layer, a solid solution having the diamond structure is formed, and when Al is large in quantity, a solution having the face-centered cubic lattice structure is formed. The solid solution means a material in which two elements are dissolved together to form a solid phase at a relatively uniform concentration as a whole. However, each solid solution has a different component ratio in a range of the solid solubility limit.

That is, the solid solution having the diamond structure is realized in the second region 22 rich in Ge, and the solid solution having the face-centered cubic lattice structure is realized in the first region 21 rich in Al. What gives an indication when cutting a crystal to carve out the surface is the surface energy, and as shown in Table 19 in FIG. 5, it is known that when comparing Ge and Al with each other with respect to the surface energy per unit area, Ge is higher in any plane directions. In other words, in the metal eutectic layer 20, a plurality of first regions 21 having the first metal as a main component and having the face-centered cubic lattice structure, and a plurality of second regions 22 having the second metal as a main component and having the diamond structure are present, and are adjacent to each other.

As shown in FIG. 3, a part of the second region 22 reaches the boundary with the base body 10. Further, the second region 22 extends from the lid body 30 to the base body 10. In other words, the second region 22 reaches the boundary with the base body 10. That is, the second region 22 reaches the base body 10 regardless of the distance from the lid body 30. At the same time, the second region 22 rich in Ge contains Al within a range not exceeding the solid solubility limit to Ge. Further, the component ratio of Ge and Al in the second region 22 is relatively uniform and does not depend on the distance from the lid body 30. From the viewpoint of the surface energy, the bonding strength is higher when the second region 22 rich in Ge reaches the boundary with the base body 10. More preferably, the portion where the second region 22 rich in Ge extends from the lid body 30 to the base body 10 is larger in amount.

Meanwhile, on the boundary between the lid body 30 and the metal eutectic layer 20 in FIG. 3, since the second bonding part 16 made of Ge is directly deposited on the lid body 30 (FIG. 4), Ge is dispersed inside the silicon as the lid body 30. That is, the second region 22 mainly made of Ge has a fine uneven shape in a boundary portion (the dotted line in FIG. 3) with the lid body 30 to increase the contact area to make the bonding strength high.

### Bonding Method in Bonding Region

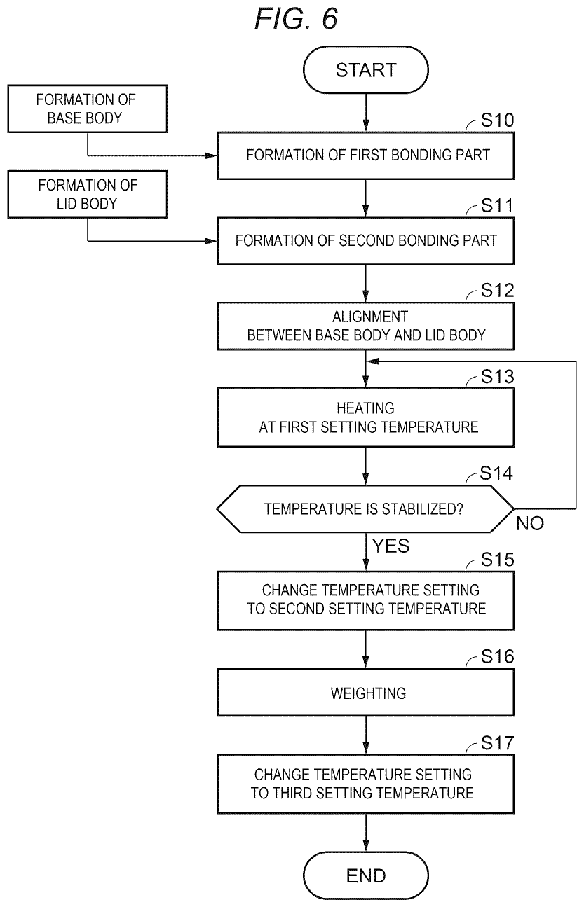

FIG. 6 is a flowchart representing a flow of the bonding method.

Here, a method of bonding the base body 10 and the lid body 30 to each other will be described with reference mainly to FIG. 6 with the inclusion of other drawings as appropriate.

In step S10, the first bonding part 15 is provided to the base body 10. Note that the description will be presented assuming that the base body 10 including the sensor element 80 is formed prior to step S10.

As shown in FIG. 4, the first bonding part 15 has the two-layer structure of the barrier layer 12 and the first metal layer 13. In a preferred example, the barrier layer 12 has the two-layer structure of Ti and TiN. The first metal layer 13 is an AlCu layer, and in a preferred example, the Cu content is assumed to be 0.1 to 1.0 wt %, and the layer thickness is assumed to be about 10,000 Å. The first bonding part 15 is deposited using, for example, a DC sputtering method, and is then patterned in accordance with the bonding region 20a.

In step S11, the second bonding part 16 is provided to the lid body 30. Note that the description will be presented assuming that the lid body 30 including the recessed part 35 is formed prior to step S11. Further, it is possible to perform the formation of the base body 10 and the formation of the lid body 30 in parallel in separate steps.

As shown in FIG. 4, the second bonding part 16 is a Ge layer as the second metal. In the present embodiment, the second bonding part 16 made of Ge is deposited directly on the silicon substrate constituting the lid body 30. In a preferred example, after depositing a Ge layer with a thickness of about 2,000 to 30,000 Å using a DC sputtering method, patterning is performed in accordance with the bonding region 20a to form the second bonding part 16. Note that the first bonding part 15 and the second bonding part 16 may be formed using an RF sputtering method as long as a desired film thickness can be obtained.

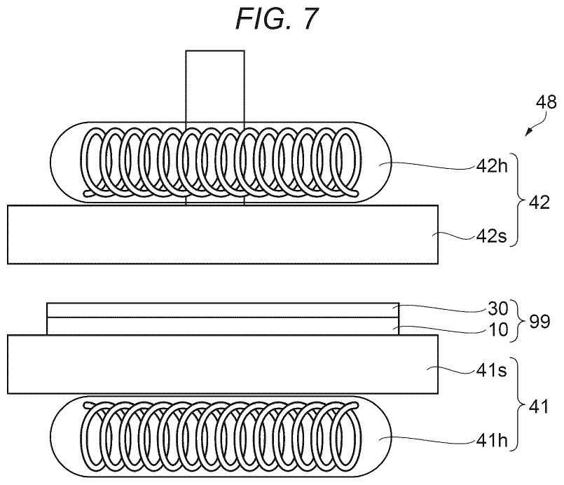

FIG. 7 is a side view illustrating a schematic configuration of a bonding apparatus. Note that a state in which the base body 10 and the lid body 30 are stacked on one another but are not bonded is referred to as a stacked body 99 for the sake of convenience of explanation.

The bonding apparatus 48 is disposed in a chamber (not shown), and includes a heating jig 41, a weighting jig 42, and so on. The heating jig 41 includes a metal stage 41s on which the stacked body 99 is placed, and a heater 41h such as a sheathed heater. The weighting jig 42 includes a stage 42s opposed to the stage 41s and a heater 42h such as a sheathed heater. Note that the heater is not limited to the sheathed heater, and may be, for example, a carbon heater as long as the heater can heat the object.

In step S12, the position of the bonding region 20a is adjusted to set the state of the stacked body 99 in which the base body 10 and the lid body 30 are stacked on one another, and then set the stacked body 99 in the heating jig 41 of the bonding apparatus 48. Particularly, as shown in FIG. 7, the stacked body 99 in a state in which the base body 10 is placed at down side is placed on the stage 41s of the heating jig 41. Note that the stacked body 99 may be placed on the heating jig 41 in a state in which the lid body 30 is placed at down side. Further, after adjusting the position of the bonding region 20a, the base body 10 and the lid body 30 may be temporarily fixed with fixing pins (not shown).

In step S12, the weighting jig 42 and the stacked body 99 are not in contact with each other and are in a separate state. Note that the stacked body 99 may be in a state of a large-sized substrate in which a plurality of sensor elements 80 are arranged. Accordingly, the base body 10 and the lid body 30 may have the same size. In addition, the inside of the chamber is preferably an environment in which moisture is removed as much as possible and is filled with an inert gas such as N₂ or Ar. Alternatively, an atmospheric pressure state may be adopted, or a vacuum state may be achieved by reducing the pressure. For example, when the sensor element 80 is an acceleration sensor, the inside of the chamber is preferably in an atmospheric pressure state. This is because the damping effect due to the atmospheric pressure may improve the characteristics of the acceleration sensor. Further, when the sensor element 80 is an angular velocity sensor, a vacuum state with the pressure of 0.1 to 10 Pa is preferable. This is because the vibration characteristics are good in such a vacuum state.

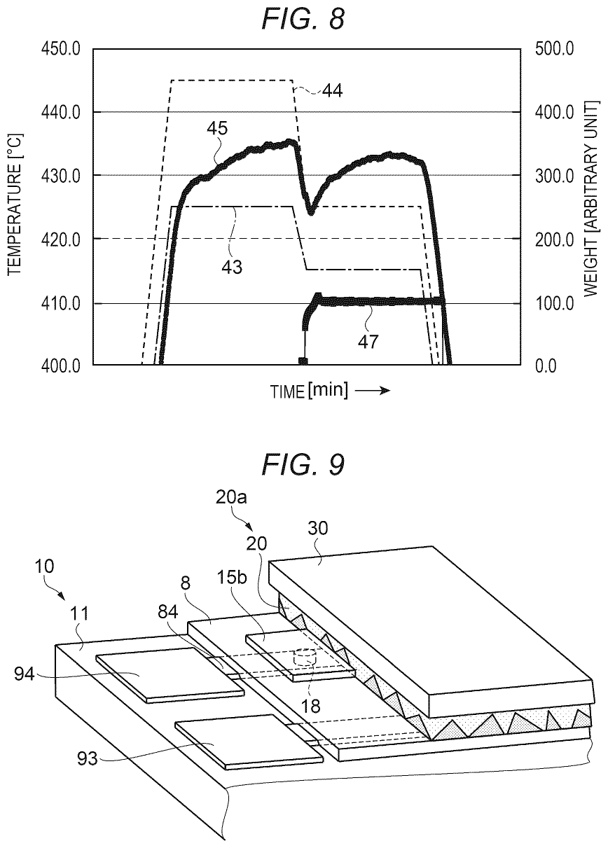

FIG. 8 is a graph showing an example of a temperature profile in the heating step. The horizontal axis represents the elapsed time (minutes), the left vertical axis represents the temperature (° C.), and the right vertical axis represents the weight (arbitrary unit).

In FIG. 8, a graph 43 represents the setting temperature of the heating jig 41, and a graph 44 represents the setting temperature of the weighting jig 42. A graph 45 represents the temperature of the stacked body 99. A graph 47 represents a state of applying a weight.

In step S13, a heating step of heating the bonding apparatus 48 is performed. In the heating step, the heating jig 41 and the weighting jig 42 are both heated to a first setting temperature equal to or higher than 400° C. Note that the eutectic temperature of AlGe is 420° C.

FIG. 8 shows an example of a temperature profile in a preferred example, and as shown in graph 43, a temperature of 425° C. is set as the first setting temperature in the heating jig 41. Note that the temperature is not limited to 425° C., and the temperature no lower than 415° C. and no higher than 425° C. may be adopted.

Further, as shown in the graph 44, in the weighting jig 42, a temperature 445° C. is set as the first setting temperature. Note that the temperature is not limited to 445° C., and the temperature no lower than 420° C. and no higher than 450° C. may be adopted.

In step S14, it is determined whether the temperature of the stacked body 99 is stabilized by heating at the first setting temperature. When the temperature is stabilized, the process proceeds to step S15. When the temperature is not stabilized, heating at the first setting temperature in step S13 is continued. In the case of FIG. 8, as shown in the graph 45, since the temperature is stabilized at about 435° C., the process proceeds to step S15. On this occasion, although the temperature of the stacked body 99 exceeds the eutectic temperature of AlGe of 420° C., since the weight is not applied, the formation of the metal eutectic layer 20 of AlGe does not significantly progress but is limited. By setting the first setting temperature to 425° C. in the heating jig 41 and 445° C. in the weighting jig 42, a sufficient heat amount can be transferred to the stacked body 99.

In step S15, the heating setting is changed to the second setting temperature lower than the first setting temperature. In the case of FIG. 8, the heating jig 41 is changed from 425° C. of the first setting temperature to 415° C. of the second setting temperature. Note that the temperature is not limited to 415° C., and the temperature no lower than 410° C. and no higher than 420° C. may be adopted. Similarly, the weighting jig 42 is changed from 445° C. of the first setting temperature to 425° C. of the second setting temperature. Note that the temperature is not limited to 425° C., and the temperature no lower than 410° C. and no higher than 430° C. may be adopted.

The reason that the heating setting is changed to the second setting temperature lower than the first setting temperature in step S15 described here is to prevent an excessive rise in temperature of the stacked body 99 which occurs when the weighting jig 42 is brought into contact with the stacked body 99. Note that it is presumed that the excessive rise in temperature is caused by the fact that there is no escape of the heat due to the adhesion of the weighting jig 42 to the stacked body 99. When the temperature of the stacked body 99 excessively rises, the metal eutectic layer 20 may be rapidly liquefied, and may protrude from the designed bonding region 20a in some cases. By setting the second setting temperature to be lower than the first setting temperature, a rapid liquefaction phenomenon and protrusion of the metal eutectic layer 20 can be prevented.

In step S16, the weighting jig 42 is lowered to make contact with the stacked body 99, and then the weight is applied for a predetermined time. When the upper side of the stacked body 99 is the lid body 30, the weighting jig 42 makes contact with the lid body 30, and when the upper side of the stacked body 99 is the base body 10, the weighting jig 42 makes contact with the base body 10. As shown in the graph 47 of FIG. 8, the weight is applied after the setting temperature is lowered. In the case of FIG. 8, a load of about 100 in an arbitrary unit is applied for a predetermined time. Further, as shown in the graph 45, the temperature of the stacked body 99 decreases to about 425° C. before the weight is applied, and the temperature gradually rises to about 433° C. in synchronization with the application of the weight.

In step S17, the heating setting is changed to a third setting temperature lower than the second setting temperature. In the case of FIG. 8, the heating jig 41 is changed from 415° C. of the second setting temperature to 100° C. of the third setting temperature. Note that the temperature is not limited to 100° C., and may be, for example, the room temperature. Similarly, the weighting jig 42 is changed from 425° C. of the second setting temperature to 100° C. of the third setting temperature. Note that the temperature is not limited to 100° C., and may be, for example, the room temperature. On this occasion, the weight is released after the temperature of the stacked body 99 decreases to a level lower than the eutectic temperature of AlGe of 420° C. That is, the predetermined time for which the weight is applied is terminated after the temperature decreases to the level equal to or lower than the eutectic temperature of 420° C. In this way, it is possible to suppress the eutectic reaction in a short time to suppress the hillock to be generated in the interconnection layer 7 including the interconnections 81 to 83. Accordingly, the inertial sensor 100 having the long-term reliability can be provided.

Due to the bonding method described above, the metal eutectic layer 20 shown in FIG. 3 is formed in the bonding region 20a, and the base body 10 and the lid body 30 are firmly bonded to each other to complete the inertial sensor 100. In particular, by performing the heating step according to the temperature profile described above and the weighting step, the good eutectic bonding can be realized without leaving the unreacted layer of Al or Ge in the eutectic layer.

In other words, the manufacturing method of bonding the base body 10 provided with the sensor element 80 and the lid body 30 covering the sensor element 80 to each other in the bonding region 20a surrounding the sensor element 80 includes forming the first bonding part 15 mainly made of the first metal in the bonding region 20a in the base body 10, forming the second bonding part 16 mainly made of the second metal in the bonding region 20a in the lid body 30, stacking the base body 10 and the lid body 30 so that the first bonding part 15 and the second bonding part 16 overlap each other to form the stacked body 99, a heating step of heating the stacked body 99, and a weighting step of applying a weight to the stacked body 99. Further, in the heating step, heating is started at the first setting temperature, then the heating setting is changed to the second setting temperature lower than the first setting temperature after the temperature of the stacked body 99 is stabilized, and then the weighting step is performed. Then, when the weighting step ends, the temperature setting is changed to a third setting temperature lower than the second setting temperature.

### Potential of Lid Body

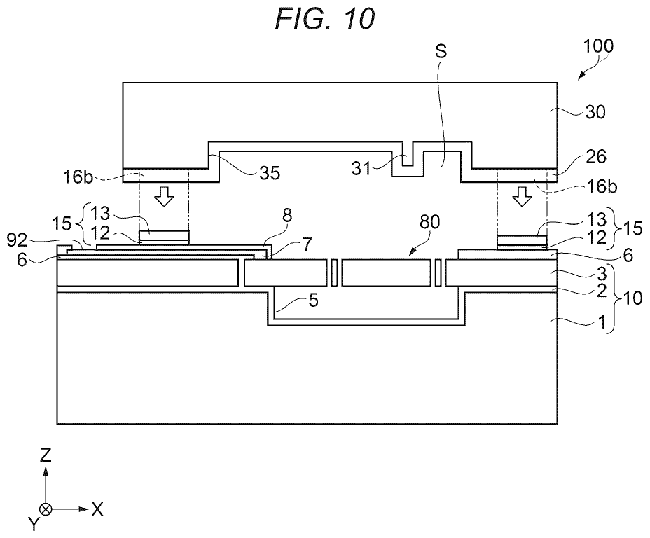

FIG. 9 is a perspective view of an essential part showing an electrical interconnection structure of the metal eutectic layer, and is an enlarged perspective view of the periphery of the terminal 94 in FIG. 1.

As shown in FIG. 9, the metal eutectic layer 20 is electrically coupled to the terminal 94, which is a GND terminal, with a protruding part 15b of the first bonding part 15 (FIG. 4). The protruding part 15b is an interconnection pattern formed together with the first bonding part 15 and protrudes from the bonding region 20a toward the terminal 94. Since the second bonding part 16 (FIG. 4) does not have a portion opposed to the protruding part 15b, the protruding part 15b functions as an electrical interconnection drawn from the metal eutectic layer 20.

The protruding part 15b is disposed to overlap the interconnection 84 leading to the terminal 94 via the insulating layer 8. A contact part 18 having conductivity is disposed in a portion of the insulating layer 8 where the interconnection 84 and the protruding part 15b overlap each other.

Thus, the terminal 94 and the metal eutectic layer 20 are electrically coupled to each other via the interconnection 84, the contact part 18, and the protruding part 15b. Note that the potential is not limited to the GND potential, and may sufficiently be an electrically stable potential such as a constant potential including a power supply potential. In other words, the lid body 30 is electrically coupled to the power supply interconnection of the base body 10 via the metal eutectic layer 20.

Further, in the above description, the sensor element 80 is assumed to be an acceleration sensor in the Z direction, but this is not a limitation, and the sensor element 80 is sufficiently an electronic component which requires an airtight environment, and may be an MEMS device such as an angular velocity sensor, or a timing device such as a crystal vibrator or a ceramic oscillator.

As described hereinabove, according to the inertial sensor 100 and the method of manufacturing the inertial sensor 100 related to the present embodiment, the following advantages can be obtained.

The inertial sensor 100 is a capacitance change type inertial sensor, and includes the base body 10, the lid body 30, the sensor element 80 as a functional element disposed between the base body 10 and the lid body 30, and the metal eutectic layer 20 for bonding the base body 10 and the lid body 30 to each other on the periphery of the sensor element 80, wherein in the metal eutectic layer 20, the plurality of first regions having the first metal as a main component and having the face-centered cubic lattice structure, and the plurality of second regions having the second metal as a main component and having the diamond structure are present, and are adjacent to each other.

According to this, since the base body 10 and the lid body 30 are bonded to each other with the metal eutectic layer in which the first regions 21 having the face-centered cubic lattice structure and the second regions 22 having the diamond structure are randomly fitted, a high bonding strength can be obtained. Further, the AlGe eutectic layer is formed in the entire area of the bonding region 20a, which is excellent in reliability.

Accordingly, it is possible to provide the inertial sensor 100 which is high in bonding strength between the base body 10 and the lid body 30 and is excellent in long-term reliability.

Further, the second regions 22 reach the boundary with the base body 10.

According to this, since the second regions 22 rich in Ge reach the boundary with the base body 10, the bonding strength in the bonding region 20a increases.

Further, the second regions 22 extend from the lid body 30 to the base body 10.

According to this, the bonding strength in the bonding region 20a becomes higher.

Further, a portion where the second regions 22 extend is larger in amount in the second regions 22 than in the first regions 21. According to this, since the extending portion of the second region 22 rich in Ge is large in amount, the bonding strength in the bonding region 20a increases.

In addition, the contact area between the first region 21 and the second region 22 is larger than the area of the bonding region 20a in which the base body 10 and the lid body 30 are bonded to each other with the metal eutectic layer 20.

According to this, since the first region 21 and the second region 22 are randomly fitted with a wide contact area, the bonding strength is made extremely high.

Further, the lid body 30 is electrically coupled to the power supply interconnection of the base body 10 via the metal eutectic layer 20. According to this, since the lid body 30 becomes the power supply potential and is electrically stabilized, it is difficult to be affected by noise, and the operation of the sensor element 80 can be stabilized.

Further, the first metal is Al, and the second metal is Ge.

According to this, the metal eutectic layer 20 high in bonding strength can be formed.

The method of manufacturing the inertial sensor 100 is the method of bonding the base body 10 provided with the sensor element 80 and the lid body 30 covering the sensor element 80 to each other in the bonding region 20a surrounding the sensor element 80, the method including forming the first bonding part 15 mainly made of the first metal in the bonding region 20a in the base body 10, forming the second bonding part 16 mainly made of the second metal in the bonding region 20a in the lid body 30, adjusting the positions of the base body 10 and the lid body 30 so that the first bonding part 15 and the second bonding part 16 overlap each other and stacking the base body 10 and the lid body 30 to form the stacked body 99, a heating step of heating the stacked body 99, and a weighting step of applying a weight to the stacked body 99.

According to this manufacturing method, the temperature and the weight required for forming the eutectic layer can be applied in the heating step and the weighting step. Thus, the metal eutectic layer 20 having a high bonding strength can be formed in the bonding region 20a.

Further, in the heating step, after the temperature of the stacked body 99 is stabilized in the heating step set with the first setting temperature, the temperature setting is changed to the second setting temperature lower than the first setting temperature, and then the weighting step is performed.

According to this, it is possible to prevent an excessive rise in temperature when the weighting jig 42 is brought into contact with the stacked body 99. Thus, the metal eutectic layer 20 can be formed at an appropriate heating temperature.

Further, when the weighting step ends, the temperature setting is changed to the third setting temperature lower than the second setting temperature. According to this, the metal eutectic layer 20 can be formed at an appropriate heating temperature.

In addition, when the stacked body 99 is placed on the heating jig 41 with the base body 10 placed at down side, the weighting jig 42 is disposed above the lid body 30 in the stacked body 99, the heating jig and the weighting jig generate heat in the heating step, and in the weighting state, the weighting jig makes contact with the lid body 30 to apply the weight.

According to this, the metal eutectic layer 20 can be formed by an appropriate method using the bonding apparatus 48, and the base body 10 and the lid body 30 can be bonded to each other.

In contrast, when the stacked body 99 is placed on the heating jig 41 with the lid body 30 placed at down side, the weighting jig 42 is disposed above the base body 10 in the stacked body 99, the heating jig and the weighting jig generate heat in the heating step, and in the weighting state, the weighting jig makes contact with the base body 10 to apply the weight.

### Embodiment 2

### Aspect Different in Bonding Layer-1

FIG. 10 is a cross-sectional view of an essential part of the base body and the lid body to be bonded to each other according to Embodiment 2, and corresponds to FIG. 4.

In the embodiment described above, the description is presented assuming that the second bonding part 16 is patterned in accordance with the bonding region 20a, but this is not a limitation, and the patterning can be eliminated. Hereinafter, regions the same as those in the embodiment described above will be denoted by the same reference numerals, and redundant descriptions thereof will be omitted.

In the present embodiment, a Ge layer is deposited directly on the entire surface of the lid body 30, and the Ge layer is used as a bonding layer 26. Particularly, as shown in FIG. 10, a portion of the bonding layer 26 that overlaps the first bonding part 15 becomes the second bonding part 16b, and by bonding the second bonding part 16b and the first bonding part 15 to each other, the metal eutectic layer 20 can be formed. The rest of the configuration is the same as that in the description of Embodiment 1.

Even in this configuration, it is possible to provide the inertial sensor 100 which is high in bonding strength between the base body 10 and the lid body 30 and is excellent in long-term reliability. Further, since the patterning of the second bonding part is unnecessary, the number of processing steps is reduced, and the manufacturing cost can be reduced.

### Embodiment 3

### Aspect Different in Bonding Layer-2

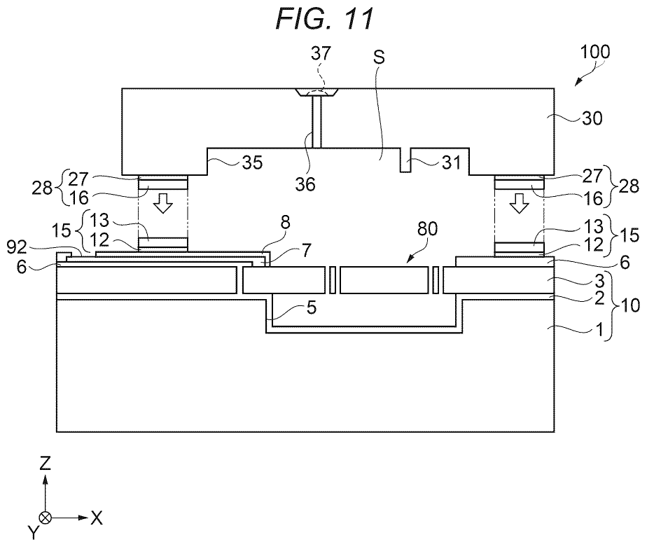

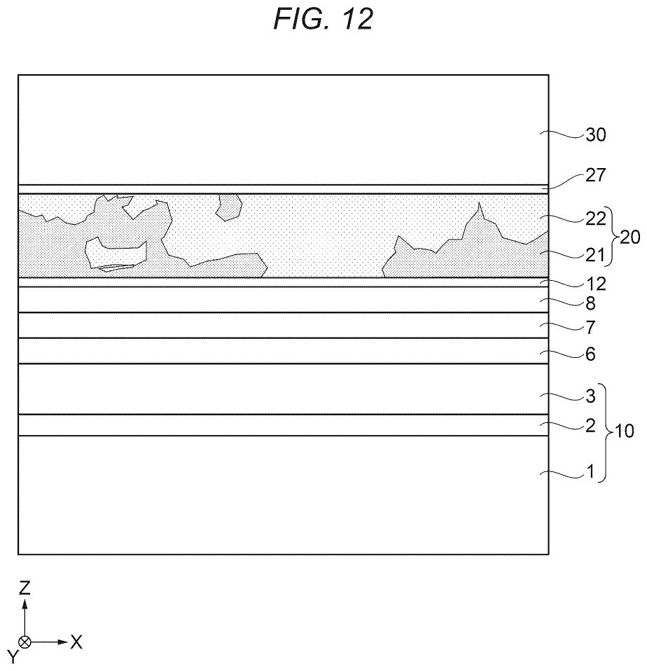

FIG. 11 is a cross-sectional view of an essential part of the base body and the lid body to be bonded to each other according to Embodiment 3, and corresponds to FIG. 4. FIG. 12 is an enlarged view of the periphery of the metal eutectic layer after bonding, and corresponds to FIG. 3.

In the above embodiment, the description is presented assuming that the second bonding part 16 is deposited directly on the lid body 30, but this is not a limitation, and a barrier layer 27 may be disposed as a foundation layer. Further, a sealing hole 36 may be provided to the lid body 30. Hereinafter, regions the same as those in the embodiment described above will be denoted by the same reference numerals, and redundant descriptions thereof will be omitted.

In the present embodiment, a second bonding part 28 has a two-layer structure. Particularly, the second bonding part 28 includes the barrier layer 27 made of a TiN layer and the second metal layer 16 made of a Ge layer. The barrier layer 27 is disposed on the silicon substrate constituting the lid body 30. The barrier layer 27 may be sufficiently made of a material having a melting point higher than the eutectic point of the metal eutectic layer 20, and may be made of Ti, Mo, W, Co, Pt, Ta, or TiN, or an alloy of any of these metals. In a preferred example, regarding the second bonding part 28, each layer is deposited using the DC sputtering method, and then patterned in accordance with the bonding region 20a to thereby form the second bonding part 28. Note that the RF sputtering method may be used.

Further, the lid body 30 is provided with the sealing hole 36 penetrating the lid body. The sealing hole 36 has a function of communicating the outside air with the inside of the housing space S when the base body 10 and the lid body 30 are bonded to each other. The sealing hole 36 is formed in a recessed portion recessed from the upper surface of the lid body 30, and can be sealed with, for example, a solder ball 37 after bonding the base body 10 and the lid body 30 to each other. Alternatively, the sealing may be made by directly melting the sealing hole 36 with a laser beam. The rest of the configuration is the same as the configuration in Embodiment 1.

By providing the sealing hole 36, it is not necessary to seal the inside of the housing space S when forming the metal eutectic layer 20, and therefore, the manufacturing efficiency can be increased.

FIG. 12 is an image obtained by faithfully tracing microscope photograph of the eutectic layer in the metal eutectic layer 20 which is formed by bonding the first bonding part 15 and the second bonding part 28 to each other with the bonding method of FIG. 6.

As shown in FIG. 12, the metal eutectic layer 20 is formed in the state where the first region 21 having the first metal of Al as the main component and the second region 22 having the second metal of Ge as the main component are adjacent to each other. The second region 22 extends widely along the lid body 30, but a part of the second region 22 reaches a boundary with the base body 10. That is, similarly to the description with reference to FIG. 3, the bonding high in bonding strength is realized by the metal eutectic layer 20.

Further, by providing the barrier layer 27, the dispersion of Ge into the lid body 30 is prevented, and the electrical contact with silicon constituting the lid body 30 is improved. That is, the ohmic contact between the metal eutectic layer 20 and the lid body 30 can be realized by the barrier layer 27.

### Embodiment 4

### Application to Inertial Measurement Device

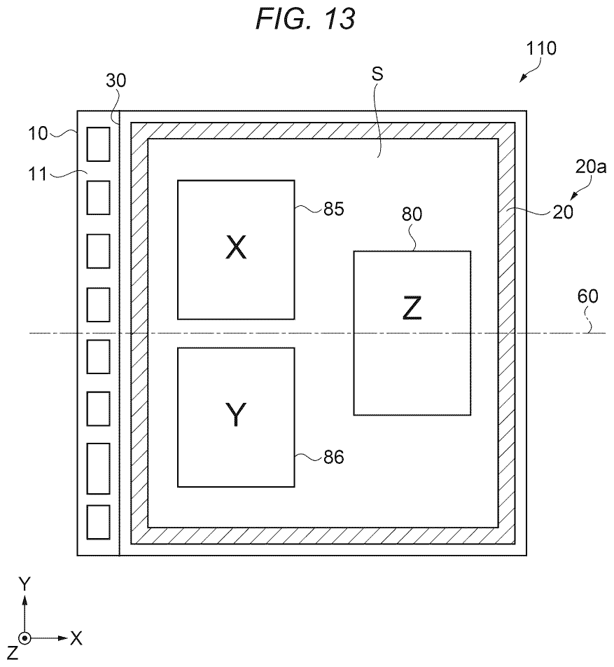

FIG. 13 is a plan view of an inertial sensor according to Embodiment 4, and corresponds to FIG. 1.

In the embodiment described above, the description is presented assuming that the inertial sensor 100 houses a single sensor element 80, but this is not a limitation, and a plurality of sensor elements may be housed. Hereinafter, regions the same as those in the embodiment described above will be denoted by the same reference numerals, and redundant descriptions thereof will be omitted.

As shown in FIG. 13, an inertial sensor 110 according to the present embodiment includes a sensor element 85 and a sensor element 86 in addition to the sensor element 80 described above.

The sensor element 85 is a capacitance change type acceleration sensor that detects the acceleration in the X direction. The sensor element 86 is a capacitance change type acceleration sensor that detects the acceleration in the Y direction. That is, the inertial sensor 110 is a triaxial acceleration sensor capable of detecting the acceleration along the three axes in the X, Y, and Z directions.

Similarly to the inertial sensor 100, the inertial sensor 110 has a configuration in which the base body 10 and the lid body 30 are bonded to each other with the metal eutectic layer 20 in the bonding region 20a, and has the housing space S inside. The three sensor elements 80, 85, and 86 are housed in the housing space S in a state in which the sensor elements 80, 85, and 86 can make a detection oscillation. In FIG. 13, the bonding region 20a is a quadrangular annular region that is slightly smaller than the outer circumferential edge of the lid body 30, but this is not a limitation. The bonding region 20a may have a polygonal shape or an elliptical shape as long as the bonding region is closed to surround the sensor elements 80, 85, and 86. However, the bonding region 20a is configured to cross extraction interconnections (not shown) in a plan view.

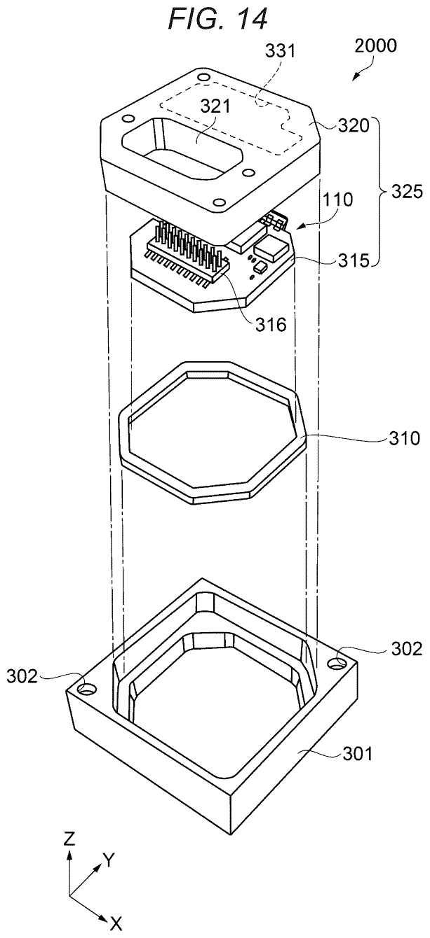

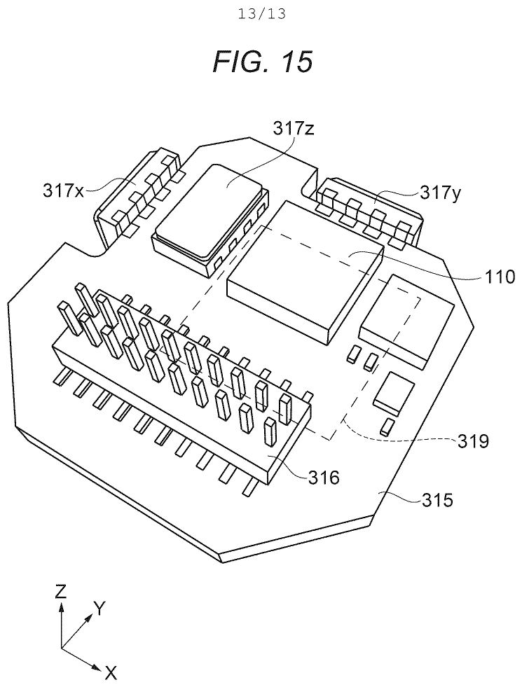

FIG. 14 is an exploded perspective view of an inertial measurement device. FIG. 15 is a perspective view of a board.

The inertial sensor 110 is installed in an inertial measurement device 2000 according to the present embodiment shown in FIG. 14. The inertial measurement device 2000 is a rectangular solid having a substantially square planer shape.

The inertial measurement device 2000 is an inertial measurement sensor unit (IMU: Inertial Measurement Unit) that detects a posture and a behavior of a mounting target body such as a car or a robot. The inertial measurement device 2000 functions as a so-called six-axis motion sensor including a triaxial acceleration sensor and angular velocity sensors around the three axes.

The inertial measurement device 2000 includes an outer case 301, a bonding member 310, and a sensor module 325 on which the inertial sensor is mounted.

An outer shape of the outer case 301 is a rectangular solid having a substantially square planar shape similarly to the whole shape of the inertial measurement device 2000, and screw holes 302 are respectively formed in the vicinity of two vertexes located in the diagonal direction of the square shape. With two screws inserted into these screw holes 302 located at the two places, the inertial measurement device 2000 can be fixed to a mounting target surface of the mounting target body such as a car.

Further, the outer case 301 has a box-like shape, and the sensor module 325 is housed in the outer case 301. Specifically, there is adopted a configuration in which the sensor module 325 is inserted into the outer case 301 with the bonding member 310 interposed therebetween.

The sensor module 325 includes an inner case 320 and a board 315.

The inner case 320 is a member that supports the board 315, and the board 315 is bonded to a lower surface of the inner case 320 via an adhesive.

Further, the inner case 320 is shaped to be fitted inside the outer case 301. The inner case 320 is provided with a recessed part 331 for preventing contact with the board 315 and an opening 321 for exposing a connector 316 described later. The inner case 320 is bonded to the outer case 301 via the bonding member 310.

Then, the board 315 on which the inertial sensor 110 is mounted will be described.

As shown in FIG. 15, the inertial sensor 110, the connector 316, an angular velocity sensor 317z for detecting angular velocity around the Z axis, and so on are mounted on a surface at the inner case 320 side as an upper surface of the board 315. An angular velocity sensor 317x for detecting the angular velocity around the X axis and an angular velocity sensor 317y for detecting the angular velocity around the Y axis are mounted on side surfaces of the board 315. The inertial sensor 100 may be mounted instead of the inertial sensor 110.

Further, a control IC 319 serving as a controller is mounted on a surface at the outer case 301 side as a lower surface of the board 315. The control IC 319 is a micro controller unit (MCU), incorporates a storage including a nonvolatile memory, an A/D converter, and so on, and controls each unit of the inertial measurement device 2000. The storage stores a program in which an order and contents for detecting the acceleration and the angular velocity are defined, a program which digitalizes detection data to be incorporated into packet data, accompanying data, and so on. Note that a plurality of other electronic components is mounted on the board 315 besides the above.

According to such an inertial measurement device 2000, since the inertial sensor 110 is used, it is possible to provide the inertial measurement device 2000 which enjoys the advantages related to the embodiments described above and is excellent in long-term reliability.

What is claimed is:

1. An inertial sensor of a capacitance change type comprising:
a base body;
a lid body;
a functional element disposed between the base body and the lid body; and
a metal eutectic layer configured to bond the base body and the lid body to each other on a periphery of the functional element, wherein
in the metal eutectic layer, a plurality of first regions having a first metal as a main component and having a face-centered cubic lattice structure, and a second region having a second metal as a main component and having a diamond structure are present, and adjacent to each other.

2. The inertial sensor according to claim 1, wherein
the second region reaches a boundary with the base body.

3. The inertial sensor according to claim 2, wherein
the second region extends from the lid body to the base body.

4. The inertial sensor according to claim 3, wherein
a portion where the second region extends is larger in amount in the second region than in the first region.

5. The inertial sensor according to claim 3, wherein
a contact area between the first region and the second region is larger than an area of a bonding region where the base body and the lid body are bonded to each other with the metal eutectic layer.

6. The inertial sensor according to claim 2, wherein
the lid body is electrically coupled to a power supply interconnection of the base body via the metal eutectic layer.

7. The inertial sensor according to claim 2, wherein
the first metal is Al, and the second metal is Ge.

8. An electronic component comprising:
a base body;
a lid body;
a functional element disposed between the base body and the lid body; and
a metal eutectic layer configured to bond the base body and the lid body to each other on a periphery of the functional element, wherein
in the metal eutectic layer, a plurality of first regions having a first metal as a main component and having a face-centered cubic lattice structure, and a second region having a second metal as a main component and having a diamond structure are present, and adjacent to each other.

9. The electronic component according to claim 8, wherein
the second region reaches a boundary with the base body.

10. The electronic component according to claim 9, wherein
the second region extends from the lid body to the base body.

11. The electronic component according to claim 10, wherein
a portion where the second region extends is larger in amount in the second region than in the first region.

12. The electronic component according to claim 10, wherein
a contact area between the first region and the second region is larger than an area of a bonding region where the base body and the lid body are bonded to each other with the metal eutectic layer.

13. The electronic component according to claim 9, wherein
the lid body is electrically coupled to a power supply interconnection of the base body via the metal eutectic layer.

14. The electronic component according to claim 9, wherein
the first metal is Al, and the second metal is Ge.

15. A method of manufacturing an inertial sensor, the method configured to bond a base body provided with a functional element and a lid body configured to cover the functional element to each other in a bonding region surrounding the functional element, the method comprising:
forming a first bonding part mainly made of a first metal in the bonding region in the base body;
forming a second bonding part mainly made of a second metal in the bonding region in the lid body;
aligning the first bonding part and the second bonding part to overlap each other and then stacking the base body and the lid body on one another to form a stacked body;
a heating step of heating the stacked body; and
a weighting step of applying a weight to the stacked body.

16. The method of manufacturing the inertial sensor according to claim 15, wherein
in the heating step, the heating is started at a first setting temperature, and
heating setting is changed to a second setting temperature lower than the first setting temperature after temperature of the stacked body is stabilized, and then the weighting step is executed.

17. The method of manufacturing the inertial sensor according to claim 16, wherein
when the weighting step ends, the heating setting is changed to a third setting temperature lower than the second setting temperature.

18. The method of manufacturing the inertial sensor according to claim 15, wherein
the stacked body is placed on a heating jig with the base body placed at down side,
a weighting jig is disposed above the lid body in the stacked body,
the heating jig and the weighting jig generate heat in the heating step, and
the weighting jig makes contact with the lid body to apply a weight in the weighting step.

19. The method of manufacturing the inertial sensor according to claim 15, wherein
the stacked body is placed on a heating jig with the lid body placed at down side,
a weighting jig is disposed above the base body in the stacked body,
the heating jig and the weighting jig generate heat in the heating step, and
the weighting jig makes contact with the base body to apply a weight in the weighting step.
